(19) United States
(12) Patent Application Publication
(10) Pub. No.: US 2021/0384176 A1
(43) Pub. Date: Dec. 9, 2021

(54) MICRO LIGHT-EMITTING DIODE DISPLAY DEVICE AND METHOD FOR FABRICATING SAME

(71) Applicant: WUHAN CHINA STAR OPTOELECTRONICS TECHNOLOGY CO., LTD., Wuhan, Hubei (CN)

(72) Inventor: Weihong YIN, Wuhan, Hubei (CN)

(21) Appl. No.: 16/965,347

(22) PCT Filed: Jun. 19, 2020
(86) PCT No.: PCT/CN2020/096972

§ 371 Date: Jul. 28, 2020

(30) Foreign Application Priority Data
Jun. 5, 2020 (CN) 202010507355.5

(51) Int. Cl. H01L 25/16; H01L 33/00

(52) U.S. Cl. CPC H01L 25/167; H01L 33/0093

(57) ABSTRACT

A method for fabricating a micro light-emitting diode display device is provided, including: providing a driving substrate including a first substrate and a driving circuit layer disposed on the first substrate, wherein the driving circuit layer includes a first electrode and a second electrode; providing a transfer substrate including a second substrate, an alignment mark, and a micro light-emitting diode, wherein the alignment mark and the micro light-emitting diode are respectively disposed on two opposite surfaces of the second substrate, and the micro light-emitting diode includes a P electrode and an N electrode; attaching the driving substrate and the transfer substrate through the alignment mark, so that the first electrode and the second electrode are electrically respectively connected to the P electrode and the N electrode; removing the alignment mark; and thinning the second substrate. A display device made by the method is also provided.

### FIELD OF INVENTION

The present disclosure relates to the technical field of display, and particularly to a micro light-emitting diode display device and a method for fabricating the same.

### BACKGROUND

Current methods for fabricating micro light-emitting diode (micro LED) display devices mainly transfer micro LEDs directly from growth substrates to driving substrates. Therefore, it is necessary to wait for driving circuit layers of the driving substrates to be formed before transferring the micro LEDs to the driving circuit layers. With the development of technology, sizes of micro LEDs have become smaller, so that intervals of the micro LEDs on the driving substrates can be shorter and density of the micro LEDs can be higher. Therefore, pixel density (pixels per inch, PPI) of micro LED display devices can be greater. For a screen of a 5-inch mobile phone with 500 PPI, it comprises about 8 million micro LEDs.

Current mass transfer technology generally requires several transfers to transfer a plurality of micro LEDs required for a screen of a mobile phone. Therefore, it is extremely time-consuming to transfer the micro LEDs. In addition, the current mass transfer technology needs to set a plurality of alignment marks in display areas of driving substrates before transfers to ensure accuracy of the transfers. However, under increasing demand of PPI, when size of the alignment marks is greater than size of pixels, it will affect a display effect of a display device.

### SUMMARY OF DISCLOSURE

In order to solve the technical problem that a display area of a driving substrate in a current display device is provided with alignment marks for transferring micro light-emitting diodes, which affects display effect, the present disclosure provides a method for fabricating a micro light-emitting diode display device comprising: providing a driving substrate comprising a first display area, and structurally comprising a first substrate and a driving circuit layer disposed on the first substrate, wherein the driving circuit layer in the first display area comprises a first electrode and a second electrode; providing a transfer substrate comprising a second display area, and structurally comprising a second substrate, an alignment mark, and a micro light-emitting diode, wherein the alignment mark and the micro light-emitting diode are respectively disposed on two opposite surfaces of the second substrate in the second display area, and the micro light-emitting diode comprises a P electrode and an N electrode; attaching the driving substrate and the transfer substrate through the alignment mark, so that the first electrode and the second electrode of the driving circuit layer are electrically connected to the P electrode and the N electrode of the micro light-emitting diode, respectively; and removing the alignment mark.

In an embodiment, providing the transfer substrate comprises: providing the second substrate; forming the alignment mark on a first surface of the second substrate in the second display area; forming the micro light-emitting diode on a growth substrate, and transferring the micro light-emitting diode from the growth substrate to a second surface of the second substrate in the second display area. The first surface and the second surface are the two opposite surfaces of the second substrate.

In an embodiment, providing the transfer substrate further comprises: detecting defects of the micro light-emitting diode after transferring the micro light-emitting diode to the second substrate, and transferring another micro light-emitting diode to replace the micro light-emitting diode when the micro light-emitting diode is detected as a defective product.

In an embodiment, providing the driving substrate comprises: providing the first substrate, and forming the driving circuit layer on the first substrate. Furthermore, forming the driving circuit layer and transferring the micro light-emitting diode are performed simultaneously.

In an embodiment, the method further comprises thinning the second substrate while removing the alignment mark.

In an embodiment, the micro light-emitting diode is a lateral or vertical micro light-emitting diode.

In an embodiment, the first display area of the driving substrate is not provided with an alignment mark for transferring the micro light-emitting diode thereon.

The present disclosure further provides a micro light-emitting diode display device comprising a driving substrate comprising a first display area, and a transfer substrate comprising a second display area. The driving substrate structurally comprises a first substrate and a driving circuit layer disposed on the first substrate. The driving circuit layer in the first display area comprises a first electrode and a second electrode. The transfer substrate structurally comprises a second substrate and a micro light-emitting diode disposed on a surface of the second substrate in the second display area. The micro light-emitting diode comprises a P electrode and an N electrode. The transfer substrate is attached to the driving substrate. The second display area is aligned with the first display area. The P electrode and the N electrode of the micro light-emitting diode are electrically connected to the first electrode and the second electrode of the driving circuit layer, respectively.

In an embodiment, the micro light-emitting diode is a lateral or vertical micro light-emitting diode.

In an embodiment, the first display area of the driving substrate is not provided with an alignment mark for transferring the micro light-emitting diode thereon.

Compared with current methods for fabricating micro light-emitting diode display devices, in a method of the present invention, (1) an alignment mark and a micro light-emitting diode are respectively disposed on two opposite surfaces of a display area of a second substrate to form a transfer substrate, (2) a P electrode and an N electrode of a micro light-emitting diode are respectively electrically connected to a first electrode and a second electrode of a driving circuit layer of a display area of a driving substrate by attaching the driving substrate and the transfer substrate through the alignment mark, and (3) the alignment mark is removed, thereby achieving the following effects. (1) Formation of the driving circuit layer of the driving substrate and transfer of the micro light-emitting diode to the second substrate can be performed simultaneously to reduce the time required for fabricating. (2) The alignment mark on a display area of the transfer substrate will be removed eventually, and there is no need to dispose alignment marks in the display area of the driving substrate, so display effect of a micro light-emitting diode display device finally fabricated will not be affected.

### BRIEF DESCRIPTION OF DRAWINGS

In order to more clearly illustrate the technical solutions in the embodiments of the present disclosure, a brief description of accompanying drawings used in the description of the embodiments of the present disclosure will be given below. Obviously, the accompanying drawings in the following description are merely some embodiments of the present disclosure. For those skilled in the art, other drawings may be obtained from these accompanying drawings without creative labor.

FIG. 1 is a schematic diagram of a driving substrate according to an embodiment of the present disclosure.

FIG. 2 is a schematic cross-sectional view of the driving substrate of FIG. 1 along line A-A′.

FIG. 3 is a schematic diagram of a transfer substrate according to an embodiment of the present disclosure.

FIG. 4 is a schematic cross-sectional view of the transfer substrate of FIG. 3 along line B-B′.

FIG. 5 is a schematic diagram of a second substrate and alignment marks of FIG. 4.

FIG. 6 is a schematic cross-sectional view of a growth substrate provided with micro light-emitting diodes according to an embodiment of the disclosure.

FIG. 7 is a schematic diagram of the micro light-emitting diodes of FIG. 4 having a lateral structure.

FIG. 8 is a second schematic diagram of the micro light-emitting diodes of FIG. 4 having a vertical structure.

FIG. 9 is a schematic diagram showing the driving substrate of FIG. 1 and the transfer substrate of FIG. 3 are disposed oppositely.

FIG. 10 is a schematic diagram showing the driving substrate of FIG. 1 and the transfer substrate of FIG. 3 are attached to each other.

FIG. 11 is a front view of the attached driving substrate and transfer substrate of FIG. 10.

FIG. 12 is a schematic cross-sectional view of the attached driving substrate and transfer substrate of FIG. 11 along line C-C′.

FIG. 13 is a schematic diagram showing that the alignment marks of FIG. 12 are removed and the second substrate of FIG. 12 is thinned.

FIG. 14 is a schematic diagram of a micro light-emitting diode display device according to an embodiment of the present disclosure.

FIG. 15 is a schematic cross-sectional view of the micro light-emitting diode display device of FIG. 14.

### DETAILED DESCRIPTION

The present disclosure provides a method for fabricating a micro light-emitting diode display device comprising the following steps.

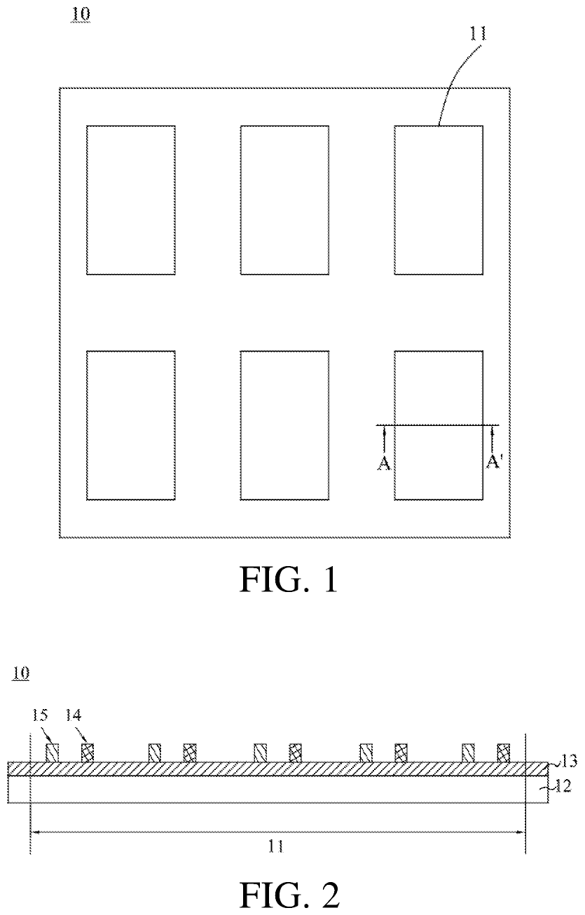

Step 1: please refer to FIG. 1 and FIG. 2, providing a driving substrate 10. The driving substrate 10 comprises a plurality of first display areas 11 arranged in an array. The driving substrate 10 structurally comprises a first substrate 12 and a driving circuit layer 13 disposed on the first substrate 12. The driving circuit layer 13 in each of the first display areas 11 comprises a plurality of first electrodes 14 and a plurality of second electrodes 15.

Specifically, Step 1 of providing the driving substrate 10 comprises Step 11 and Step 12.

Step 11: providing the first substrate 12. The first substrate 12 may be a rigid substrate made of glass, such as quartz glass, high-silica glass, borosilicate glass, soda-lime glass, and aluminosilicate glass. The first substrate 12 may also be a flexible substrate made of a flexible insulating polymer material, such as polyimide (PI), polycarbonate (PC), polyether sulfone (PES), polyethylene terephthalate (PET), polyethylene naphthalate (PEN), and fiber-reinforced polymer (FRP). The first substrate 12 may be transparent, translucent, or opaque.

Step 12: forming the driving circuit layer 13 on the first substrate 11 to obtain the driving substrate 10. The driving substrate 10 may be an active matrix substrate used in a liquid crystal display device. The driving circuit layer 13 comprises data lines, scan lines, and active elements. The active elements may be oxide thin film transistors such indium gallium zinc oxide (IGZO) thin film transistors, organic thin film transistors (organic TFTs, OTFTs), hydrogenated amorphous TFTs (a-TFT:H), low temperature poly TFTs (LTPS), or a combination thereof, but are not limited thereto. The active elements may be bottom gate type, top gate type, or double gate type thin film transistors.

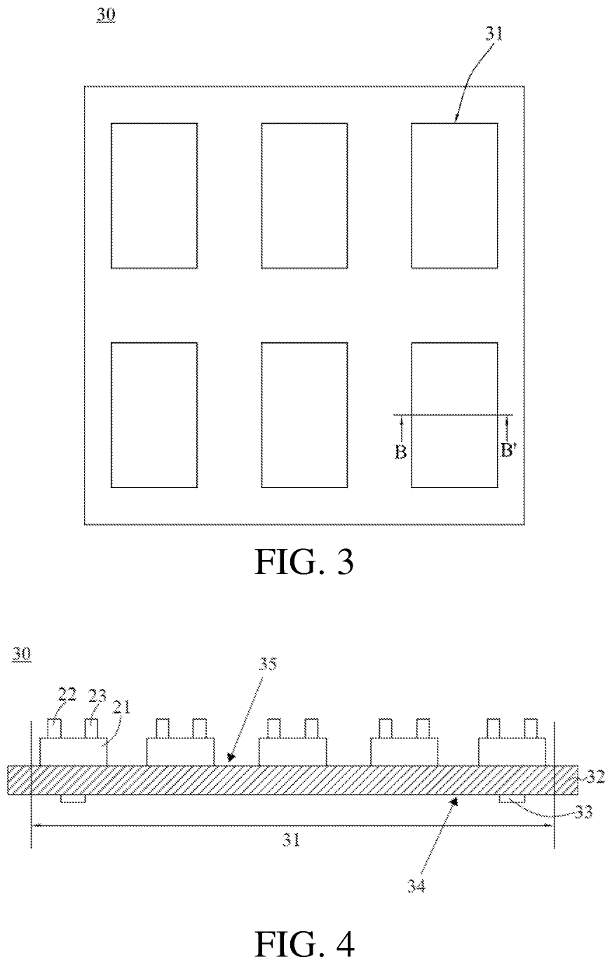

Step 2: please refer to FIG. 3 and FIG. 4, providing a transfer substrate 30. The transfer substrate 30 comprises a plurality of second display areas 31 arranged in an array. The transfer substrate 30 structurally comprises a second substrate 32, a plurality of alignment marks 33, and a plurality of micro light-emitting diodes 21. The alignment marks 33 and the micro light-emitting diodes 21 are respectively disposed on two opposite surfaces of the second substrate 32 in each of the second display areas 31. Each of the micro light-emitting diodes 21 comprises a P electrode 22 and an N electrode 23.

Specifically, Step 2 of providing a transfer substrate 30 comprises Step 21 to Step 25.

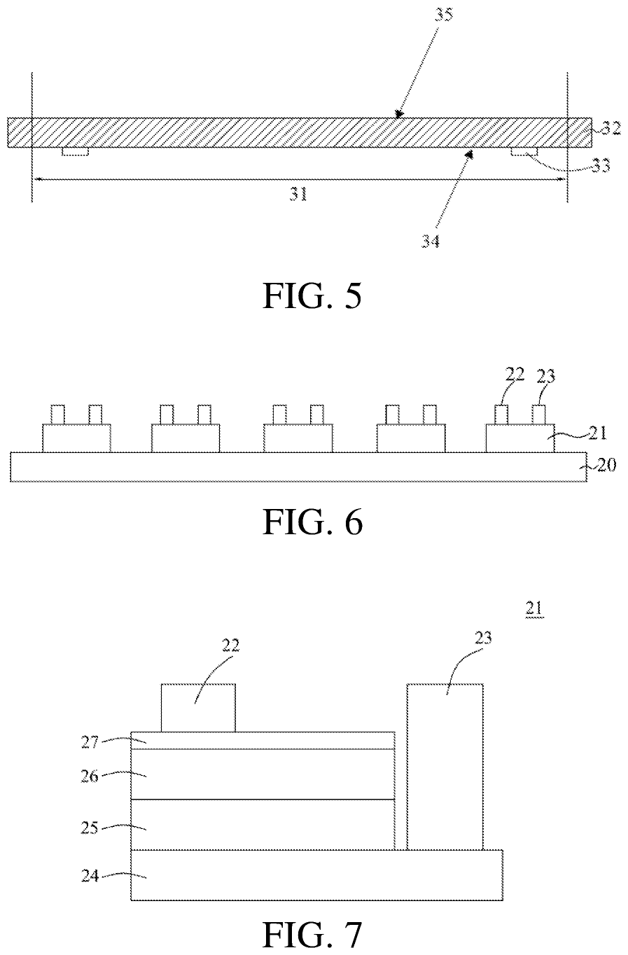

Step 21: please refer to FIG. 5, providing the second substrate 32. The second substrate 32 may be a rigid substrate made of glass, such as quartz glass, high-silica glass, borosilicate glass, soda-lime glass, and aluminosilicate glass. The second substrate 32 may also be a flexible substrate made of a flexible insulating polymer material, such as polyimide (PI), polycarbonate (PC), polyether sulfone (PES), polyethylene terephthalate (PET), polyethylene naphthalate (PEN), and fiber-reinforced polymer (FRP). The second substrate 32 may be transparent, translucent, or opaque. A material of the second substrate 32 may be same as or different from a material of the first substrate 12.

Step 22: please refer to FIG. 5, forming the alignment marks 33 on a first surface 34 of the second substrate 32 in each of the second display areas 31.

Step 23: please refer to FIG. 6, forming the micro light-emitting diodes 21 on a growth substrate 20. The micro light-emitting diodes 21 may comprise blue micro light-emitting diodes 21, red micro light-emitting diodes 21, green micro light-emitting diodes 21, or a combination thereof, but are not limited thereto.

Step 24: please refer to FIG. 4 to FIG. 6, transferring the micro light-emitting diodes 21 from the growth substrate 20 to a second surface 35 of the second substrate 32 in each of the second display areas 31. The first surface 34 and the second surface 35 are the two opposite surfaces of the second substrate 32.

Step 25: detecting whether the micro light-emitting diodes 21 have defects. When the micro light-emitting diodes 21 are detected as defective products, transferring other micro light-emitting diodes 21 to replace the micro light-emitting diodes 21.

In an embodiment, Step 1 of providing the driving substrate 10 and Step 2 of providing the transfer substrate 30 are performed simultaneously. In an embodiment, Step 12 of forming the driving circuit layer 13 on the first substrate 11 and Step 24 of transferring the micro light-emitting diodes 21 to the second substrate 32 are performed simultaneously.

In an embodiment, please refer to FIG. 7, the micro light-emitting diodes may be lateral micro light-emitting diodes, each of which comprises an N-type semiconductor layer 24, a light-emitting layer 25, a P-type semiconductor layer 26, a transparent conductive layer 27, the P electrode 22, and the N electrode 23. In this embodiment, please refer to FIG. 6 and FIG. 7, Step 23 of forming the micro light-emitting diodes 21 on the growth substrate 20 comprises: sequentially forming the N-type semiconductor layer 24, the light-emitting layer 25, the P-type semiconductor layer 26, the transparent conductive layer 27, and the P electrode 22 on the growth substrate 20; patterning the P electrode 22; etching the light-emitting layer 25, the P-type semiconductor layer 26, and the transparent conductive layer 27 to expose a part of the N-type semiconductor layer 24; and forming the N electrode 23 on the exposed N-type semiconductor layer 24.

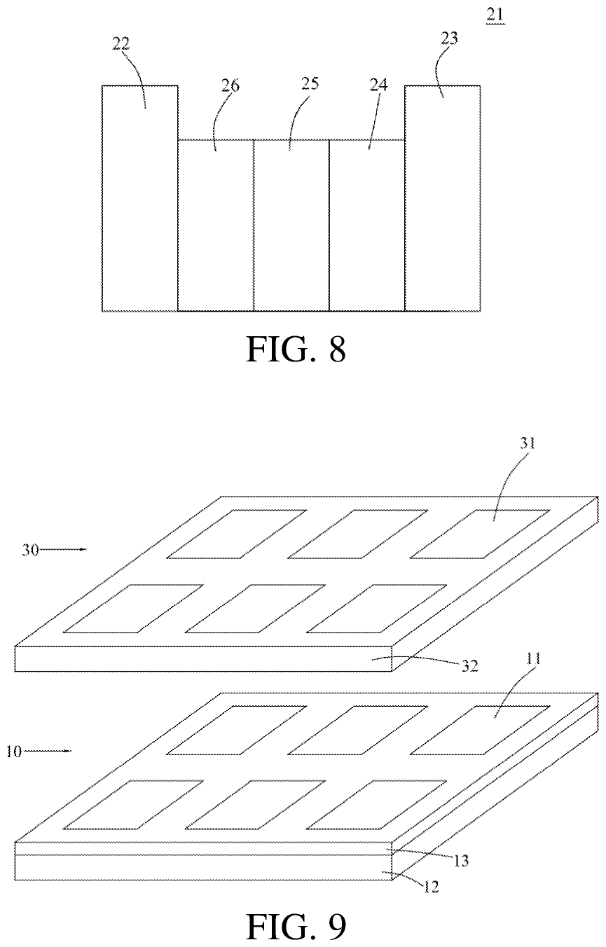

In an embodiment, please refer to FIG. 8, the micro light-emitting diodes may be vertical micro light-emitting diodes, each of which comprises the N electrode 23, an N-type semiconductor layer 24, a light-emitting layer 25, a P-type semiconductor layer 26, and the P electrode 22. In this embodiment, Step 23 of forming the micro light-emitting diodes 21 on the growth substrate 20 comprises: sequentially forming the N electrode 23, the N-type semiconductor layer 24, the light-emitting layer 25, the P-type semiconductor layer 26, and the P electrode 22 on the growth substrate 20. A manufacturing process of vertical micro light-emitting diodes is well known in the art, so it will not be described in detail.

FIG. 7 and FIG. 8 only illustrate examples of the micro light-emitting diodes 21 of the present disclosure. Structures and shapes of the micro light-emitting diodes 21 of the present disclosure are not limited to those shown in FIG. 7 and FIG. 8. The micro light-emitting diodes 21 of the present disclosure comprises all micro light-emitting diodes having a P electrode and an N electrode. Therefore, Step 23 of forming the micro light-emitting diodes 21 on the growth substrate 20 is not limited to the above descriptions using the micro light-emitting diodes 21 shown in FIG. 7 and FIG. 8 as examples.

Please refer to FIG. 7 and FIG. 8, the N-type semiconductor layer 24 may be made of an N-type nitride, such as gallium nitride (GaN) doped with silicon (Si), but is not limited thereto. The light-emitting layer 25 may have a single quantum well (SQW) structure or a multi-quantum well (MQW) structure made of indium gallium nitride (InGaN) and gallium nitride (GaN), but is not limited thereto. The P-type semiconductor layer 26 may be made of a P-type nitride, such as gallium nitride doped with magnesium (Mg), but is not limited thereto. The transparent conductive layer 27 may be made of a metal oxide, such as indium oxide, zinc oxide, titanium oxide, magnesium oxide, or indium tin oxide (ITO), but is not limited thereto. The P electrode 22 and the N electrode 23 may be made of gold (Au), nickel (Ni), silver (Ag), copper (Cu), platinum (Pt), chromium (Cr), zinc (Zn), palladium (Pd), aluminum (Al), titanium (Ti), or an alloy thereof, such as nickel-gold alloy, palladium-gold alloy, gold-zinc alloy, but are not limited thereto. The P electrode 22 and the N electrode 23 may also be made of a metal oxide, such as indium oxide, zinc oxide, titanium oxide, magnesium oxide, and indium tin oxide. The P electrode 22 and the N electrode 23 may also be a composite electrode having a multilayer structure, such as Cr/Pt/Au, Cr/Al/Pt/Au, Ti/Al/Ti/Au, Ti/Al/Ti/Pt/Au, and Ti/Al/Pt/Au. The N-type semiconductor layer 24, the light-emitting layer 25, and the P-type semiconductor layer 26 can be made by metal-organic chemical vapor deposition (MOCVD) or metal-organic physical vapor deposition (MOPVD), but are not limited thereto. The P electrode 22, the N electrode 23, and the transparent conductive layer 27 may be made by physical vapor deposition, but are not limited thereto.

Step 3: please refer to FIG. 9 to FIG. 12, attaching the driving substrate 10 and the transfer substrate 30 through the alignment marks 33, so that each of the first display areas 11 is aligned with a corresponding second display area 31, and each of the first electrodes 14 and each of the second electrodes 15 are respectively aligned with and electrically connected to a corresponding P electrode 22 and a corresponding N electrode 23. In an embodiment, as shown in FIG. 9 to FIG. 12, the transfer substrate 30 is moved onto the driving substrate 10. Then, through the alignment marks 33, each of the second display area 31 is aligned with a corresponding first display area 11, and the P electrode 22 and the N electrode 23 of each of the micro light-emitting diodes 21 are respectively aligned with a corresponding first electrode 14 and a corresponding second electrode 15. Finally, the driving substrate 10 is attached to the transfer substrate 30, and the P electrode 22 and the N electrode 23 of each of the micro light-emitting diodes 21 are respectively electrically connected to the corresponding first electrode 14 and the corresponding second electrode 15. In an embodiment, the driving substrate 10 may be moved onto the transfer substrate 30. Then, through the alignment marks 33, each of the first display area 11 is aligned with a corresponding second display area 31, and each of the first electrodes 14 and each of the second electrodes 15 are respectively aligned with a corresponding P electrode 22 and a corresponding N electrode 23. Finally, the transfer substrate 30 is attached to the driving substrate 10, and each of the first electrodes 14 and each of the second electrodes 15 are respectively electrically connected to the corresponding P electrode 22 and the corresponding N electrode 23.

The term “electrically connect” comprises “direct electrically connect” and “indirectly electrically connect”. “Direct electrically connect” means that two components are electrically connected together without other components or materials. For example, two components are electrically connected by laser spot welding. “Indirect electrically connect” means that two components are electrically connected together through other components such as anisotropic conductive film (ACF), or other materials such as anisotropic conductive paste (ACP).

In an embodiment, the driving substrate 10 and the transfer substrate 30 may be attached by coating an insulating sealant on a periphery of each of the first display areas 11 of the driving substrate 10 and/or a periphery of each of the second display areas 31 of the transfer substrate 30. The sealant may be a thermal curing adhesive, a light curing adhesive, or a combination thereof. The sealant may also be a transparent epoxy resin or silica gel. In this embodiment, each of the first electrodes 14 and each of the second electrodes 15 may be directly or indirectly electrically connected to the corresponding P electrode 22 and the corresponding N electrode 23, respectively.

In an embodiment, an insulating sealant is coated on the driving circuit layer 13 of the driving substrate 10 and/or the second surface 35 of the second substrate 32, thereby attaching the driving substrate 10 and the transfer substrate 30. In this embodiment, each of the first electrodes 14 and each of the second electrodes 15 are directly electrically connected to the corresponding P electrode 22 and the corresponding N electrode 23 by laser spot welding, respectively.

In an embodiment, an anisotropic conductive paste is coated on the driving circuit layer 13 of the driving substrate 10 and/or the second surface 35 of the second substrate 32, thereby attaching the driving substrate 10 and the transfer substrate 30. In this embodiment, each of the first electrodes 14 and each of the second electrodes 15 are indirectly electrically connected to the corresponding P electrode 22 and the corresponding N electrode 23 through the anisotropic conductive paste, respectively, or directly electrically connected to the corresponding P electrode 22 and the corresponding N electrode 23 by laser spot welding, respectively.

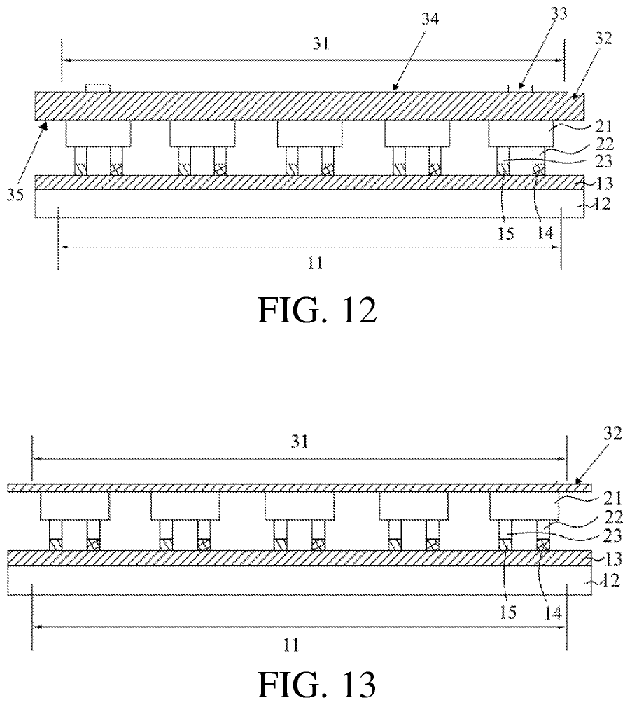

Step 4: please refer to FIG. 12 and FIG. 13, removing the alignment marks 33.

Step 5: please refer to FIG. 12 and FIG. 13, thinning the second substrate 32. In an embodiment, Step 5 can be performed simultaneously with Step 4. In an embodiment, Step 5 may be omitted.

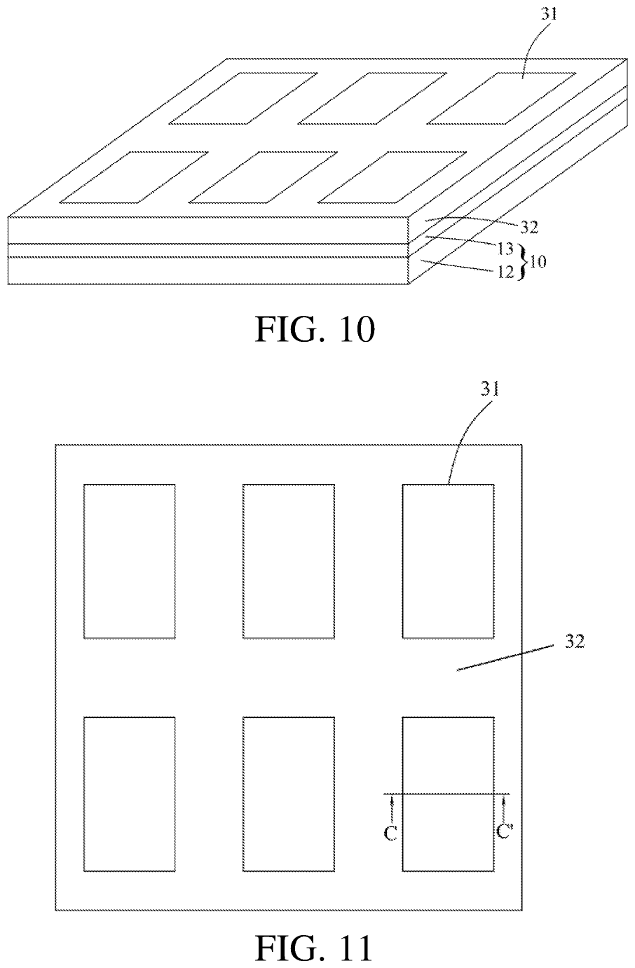

Step 5: please refer to FIG. 10 to FIG. 15, cutting the attached driving substrate 10 and transfer substrate 30 to obtain a plurality of micro light-emitting diode display devices 100.

In the method, the first display area 11 of the driving substrate 10 does not need to be provided with an alignment mark for transferring the micro light-emitting diodes 21 thereon.

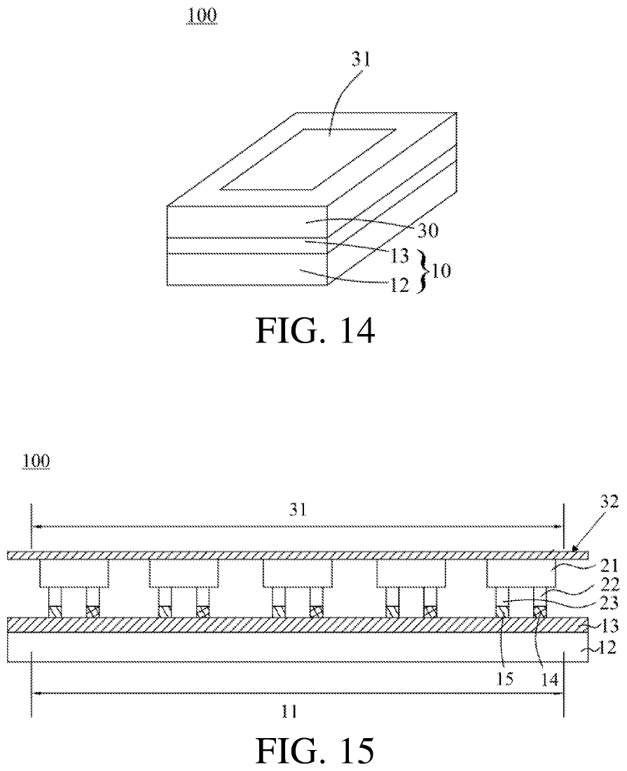

Please refer to FIG. 14 and FIG. 15, the present disclosure further provides a micro light-emitting diode display device 100 fabricated by the aforementioned method. The micro light-emitting diode display device 100 comprises a driving substrate 10 including a first display area 11, and a transfer substrate 30 including a second display area 31. The driving substrate 10 structurally comprises a first substrate 12 and a driving circuit layer 13 disposed on the first substrate 12. The driving circuit layer 13 in the first display area 11 comprises a plurality of first electrodes 14 and a plurality of second electrodes 15. The transfer substrate 30 structurally comprises a second substrate 32 and a plurality of micro light-emitting diodes 21 disposed on a surface of the second substrate 32 in the second display area 31. Each of the micro light-emitting diodes 21 comprises a P electrode 22 and an N electrode 23. The transfer substrate 30 is attached to the driving substrate 10. The second display area 31 is aligned with the first display area 11. The P electrode and the N electrode of the micro light-emitting diode are electrically connected to the first electrode and the second electrode of the driving circuit layer, respectively. The P electrode 22 and the N electrode 23 of each of the micro light-emitting diodes 21 are electrically connected to a corresponding first electrode 14 and a corresponding second electrode 15, respectively.

The first substrate 12 and the second substrate 32 may be a rigid substrate made of glass, such as quartz glass, high-silica glass, borosilicate glass, soda-lime glass, and aluminosilicate glass. The first substrate 12 and the second substrate 32 may also be a flexible substrate made of a flexible insulating polymer material, such as polyimide (PI), polycarbonate (PC), polyether sulfone (PES), polyethylene terephthalate (PET), polyethylene naphthalate (PEN), and fiber-reinforced polymer (FRP). A material of the first substrate 12 and a material of the second substrate 32 may be same or different. The first substrate 12 and the second substrate 32 may be a rigid substrate and a flexible substrate, or a flexible substrate and a rigid substrate, respectively. The first substrate 12 and the second substrate 32 may be transparent, translucent, or opaque.

The driving substrate 10 may be an active matrix substrate used in a liquid crystal display device. The driving circuit layer 13 of the driving substrate 10 comprises data lines, scan lines, and active elements. The active elements may be oxide thin film transistors, organic thin film transistors, hydrogenated amorphous thin film transistors, low temperature poly thin film transistors, or a combination thereof, but are not limited thereto. The active elements may be bottom gate type, top gate type, or double gate type thin film transistors.

In an embodiment, please refer to FIG. 7, the micro light-emitting diodes may be lateral micro light-emitting diodes, each of which comprises an N-type semiconductor layer 24, a light-emitting layer 25, a P-type semiconductor layer 26, a transparent conductive layer 27, and the P electrode 22 that are sequentially stacked, and the N electrode 23 disposed on the N-type semiconductor layer 24. In an embodiment, please refer to FIG. 8, the micro light-emitting diodes may be vertical micro light-emitting diodes, each of which comprises the N electrode 23, an N-type semiconductor layer 24, a light-emitting layer 25, a P-type semiconductor layer 26, and the P electrode 22 that are sequentially stacked. Materials of the N-type semiconductor layer 24, the light-emitting layer 25, the P-type semiconductor layer 26, the transparent conductive layer 27, the P electrode 22, and the N electrode 23 are as described above, and will not be described in detail herein. FIG. 7 and FIG. 8 only illustrate examples of the micro light-emitting diodes 21 of the present disclosure. Structures and shapes of the micro light-emitting diodes 21 of the present disclosure are not limited to those shown in FIG. 7 and FIG. 8. The micro light-emitting diodes 21 of the present disclosure comprises all micro light-emitting diodes having a P electrode and an N electrode.

The term “electrically connect” comprises “direct electrically connect” and “indirectly electrically connect”. “Direct electrically connect” means that two components are electrically connected together without other components or materials. For example, two components are electrically connected by laser spot welding. “Indirect electrically connect” means that two components are electrically connected together through other components such as anisotropic conductive film, or other materials such as anisotropic conductive paste.

In an embodiment, an insulating sealant is coated between a periphery of the first display area 11 of the drive substrate 10 and a periphery of the second display area 31 of the transfer substrate 30 for attaching the driving substrate 10 and the transfer substrate 30. The sealant may be a thermal curing adhesive, a light curing adhesive, or a combination thereof. The sealant may also be a transparent epoxy resin or silica gel. In this embodiment, each of the first electrodes 14 and each of the second electrodes 15 may be directly or indirectly electrically connected to the corresponding P electrode 22 and the corresponding N electrode 23, respectively.

In an embodiment, an insulating sealant is coated between the driving circuit layer 13 of the driving substrate 10 and a second surface 35 of the second substrate 32 for attaching the driving substrate 10 and the transfer substrate 30. In this embodiment, each of the first electrodes 14 and each of the second electrodes 15 are directly electrically connected to the corresponding P electrode 22 and the corresponding N electrode 23 by laser spot welding, respectively.

In an embodiment, an anisotropic conductive paste is coated between the driving circuit layer 13 of the driving substrate 10 and a second surface 35 of the second substrate 32 for attaching the driving substrate 10 and the transfer substrate 30. In this embodiment, each of the first electrodes 14 and each of the second electrodes 15 are indirectly electrically connected to the corresponding P electrode 22 and the corresponding N electrode 23 through the anisotropic conductive paste, respectively, or directly electrically connected to the corresponding P electrode 22 and the corresponding N electrode 23 by laser spot welding, respectively.

In the micro light-emitting diode display device 100, the first display area 11 of the driving substrate 10 is not provided with an alignment mark for transferring the micro light-emitting diodes 21 thereon.

Compared with current methods for fabricating micro light-emitting diode display devices, in a method of the present invention, (1) an alignment mark and a micro light-emitting diode are respectively disposed on two opposite surfaces of a display area of a second substrate to form a transfer substrate, (2) a P electrode and an N electrode of a micro light-emitting diode are respectively electrically connected to a first electrode and a second electrode of a driving circuit layer of a display area of a driving substrate by attaching the driving substrate and the transfer substrate through the alignment mark, and (3) the alignment mark is removed, thereby achieving the following effects. (1) Formation of the driving circuit layer of the driving substrate and transfer of the micro light-emitting diode to the second substrate can be performed simultaneously to reduce the time required for fabricating. (2) The alignment mark on a display area of the transfer substrate will be removed eventually, and there is no need to dispose alignment marks in the display area of the driving substrate, so display effect of a micro light-emitting diode display device finally fabricated will not be affected.

The present application has been described in the above preferred embodiments, but the preferred embodiments are not intended to limit the scope of the present application. Those skilled in the art may make various modifications without departing from the scope of the present application. Therefore, the scope of the present application is determined by claims.

What is claimed is:

1. A method for fabricating a micro light-emitting diode display device, comprising:
providing a driving substrate comprising a first display area, and structurally comprising a first substrate and a driving circuit layer disposed on the first substrate, wherein the driving circuit layer in the first display area comprises a first electrode and a second electrode;
providing a transfer substrate comprising a second display area, and structurally comprising a second substrate, an alignment mark, and a micro light-emitting diode, wherein the alignment mark and the micro light-emitting diode are respectively disposed on two opposite surfaces of the second substrate in the second display area, and the micro light-emitting diode comprises a P electrode and an N electrode;
attaching the driving substrate and the transfer substrate through the alignment mark, so that the first electrode and the second electrode of the driving circuit layer are electrically connected to the P electrode and the N electrode of the micro light-emitting diode, respectively; and
removing the alignment mark.

2. The method according to claim 1, wherein providing the transfer substrate comprises:
providing the second substrate;
forming the alignment mark on a first surface of the second substrate in the second display area;
forming the micro light-emitting diode on a growth substrate; and
transferring the micro light-emitting diode from the growth substrate to a second surface of the second substrate in the second display area, wherein the first surface and the second surface are the two opposite surfaces of the second substrate.

3. The method according to claim 2, wherein providing the transfer substrate further comprises:
detecting defects of the micro light-emitting diode after transferring the micro light-emitting diode to the second substrate; and
transferring another micro light-emitting diode to replace the micro light-emitting diode when the micro light-emitting diode is detected as a defective product.

4. The method according to claim 2, wherein providing the driving substrate comprises:
providing the first substrate; and
forming the driving circuit layer on the first substrate;
wherein forming the driving circuit layer and transferring the micro light-emitting diode are performed simultaneously.

5. The method according to claim 1, further comprising:
thinning the second substrate while removing the alignment mark.

6. The method according to claim 1, wherein the micro light-emitting diode is a lateral or vertical micro light-emitting diode.

7. The method according to claim 1, wherein the first display area of the driving substrate is not provided with an alignment mark for transferring the micro light-emitting diode thereon.

8. A micro light-emitting diode display device, comprising:
a driving substrate comprising a first display area, and structurally comprising a first substrate and a driving circuit layer disposed on the first substrate, wherein the driving circuit layer in the first display area comprises a first electrode and a second electrode; and
a transfer substrate comprising a second display area, and structurally comprising a second substrate and a micro light-emitting diode disposed on a surface of the second substrate in the second display area, wherein the micro light-emitting diode comprises a P electrode and an N electrode;
wherein the transfer substrate is attached to the driving substrate, the second display area is aligned with the first display area, and the P electrode and the N electrode of the micro light-emitting diode are electrically connected to the first electrode and the second electrode of the driving circuit layer, respectively.

9. The micro light-emitting diode display device according to claim 8, wherein the micro light-emitting diode is a lateral or vertical micro light-emitting diode.

10. The micro light-emitting diode display device according to claim 8, wherein the first display area of the driving substrate is not provided with an alignment mark for transferring the micro light-emitting diode thereon.
